(19) United States
(12) Patent Application Publication
(10) Pub. No.: US 2005/0191858 A1
(43) Pub. Date: Sep. 1, 2005

(54) Substrate processing method and apparatus

(76) Inventors: Akira Fukunaga, Tokyo (JP); Toshikazu Nomura, Tokyo (JP); Katsuhiko Tokushige, Tokyo (JP); Manabu Tsujimura, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 11/064,511

(22) Filed: Feb. 24, 2005

(30) Foreign Application Priority Data
Feb. 27, 2004 (JP) 2004-52985

(51) Int. Cl. H01L 21/8242; H01L 21/461; B24B 51/00

(52) U.S. Cl. 438/691; 451/5

(57) ABSTRACT

A substrate processing apparatus can process a substrate having a metal film formed thereon. The substrate processing apparatus has a process unit configured to remove a native oxide of a metal film formed on a surface of a substrate. The substrate processing apparatus also has a planarization unit configured to planarize the metal film of the substrate. The process unit may comprise a wet process unit configured to dissolve the native oxide of the metal film in a chemical liquid or a dry process unit configured to reduce or etch the native oxide of the metal film with a gas.

### BACKGROUND OF THE INVENTION

1. Field of the Invention

The present invention relates to a substrate processing method and apparatus, and more particularly to a substrate processing method and apparatus for polishing a substrate such as a semiconductor wafer to a flat mirror finish.

2. Description of the Related Art

As semiconductor devices have become more highly integrated in recent years, circuit interconnections have become finer and distances between those circuit interconnections have become smaller. In the case of photolithography, which can form interconnections that are at most 0.5 μm wide, it is required that surfaces on which pattern images are to be focused by a stepper should be as flat as possible because the depth of focus of an optical system is relatively small. In order to planarize such a semiconductor wafer, there has been used a polishing apparatus for performing chemical mechanical polishing (CMP).

This type of chemical mechanical polishing apparatus comprises a polishing table having a polishing pad (polishing cloth) attached to an upper surface of the polishing table, and a top ring for holding a substrate to be polished, such as a semiconductor wafer. The polishing table and the top ring are rotated at independent rotational speeds, respectively. The top ring presses the substrate against the polishing pad under a predetermined pressure. A polishing liquid (slurry) is supplied from a polishing liquid supply nozzle onto the polishing pad. Thus, a surface of the substrate is polished to a flat mirror finish.

When a metal film formed on a surface of a substrate is polished by the chemical mechanical polishing apparatus, the metal film is oxidized by an oxidizing agent in slurry while the oxidized film is converted into an insoluble complex by a chelating agent in the slurry. The insoluble complex is removed by abrasive particles in the slurry. Thus, the metal film is polished.

However, when a metal film of copper is formed on a surface of a substrate, a native oxide may be developed on the metal film by moisture or oxygen in the air prior to polishing. If such a native oxide is formed on the metal film, the surface of the substrate becomes unlikely to be converted into a complex by a chelating agent. Further, the native oxide is more difficult to polish than the complex. Accordingly, when the native oxide is formed so as to have uneven film thicknesses, the substrate may have some local areas that are not sufficiently polished. In such a case, uniform planarization cannot be achieved.

### SUMMARY OF THE INVENTION

The present invention has been made in view of the above drawbacks. It is, therefore, an object of the present invention to provide a substrate processing method and apparatus which can planarize a metal film formed on a substrate in a state such that a native oxide of the metal film is removed and thus achieve uniform planarization of the substrate.

According to a first aspect of the present invention, there is provided a method of processing a substrate having a metal film formed thereon. According to this method, the metal film formed on the substrate is planarized after a native oxide of the metal film is removed from the substrate. Thus, the metal film formed on the substrate can be planarized in a state such that the native oxide of the metal film has been removed. Accordingly, uniform planarization of the substrate can be achieved with high repeatability.

A wet process using a chemical liquid capable of dissolving the native oxide of the metal film on the substrate may be used to remove the native oxide of the metal film formed on the substrate. The chemical liquid may comprise an acidic chemical liquid or a chelating agent solution for forming a soluble complex. Specifically, when the metal film formed on the substrate is made of copper, the chemical liquid may include inorganic acids such as hydrofluoric acid, sulfuric acid, hydrochloric acid, and phosphoric acid, organic acids such as formic acid, acetic acid, propionic acid, oxalic acid, malonic acid, succinic acid, and malic acid, halide, carboxylic acid, salt of carboxylic acid, or a chelating agent solution for forming a soluble complex, for example, an alkali solution of amino acid such as ammonia, ethylene diamine tetraacetic acid (EDTA), or glycine.

Alternatively, a dry process using a process gas capable of reducing or etching the native oxide of the metal film on the substrate may be used to remove the native oxide of the metal film formed on the substrate. In this case, a mixed gas of hydrogen and argon may be used as a process gas. Hydrogen plasma generated by electron cyclotron resonance (ECR) may be applied to the surface of the substrate to etch the native oxide on the surface of the wafer. Depending upon properties of a process gas to be used, the surface of the substrate may be etched by reactive ion etching (RIE) or by magnetically enhanced reactive ion etching (MERIE). Instead of hydrogen, ammonia or the like can also be used as a process gas. Alternatively, hydrogen, ammonia, or organic acid such as formic acid or acetic acid may be heated to several hundreds degrees centigrade to form a reducing atmosphere to thereby reduce and remove the native oxide of the surface of the substrate. Further, the planarizing process may comprise a chemical mechanical polishing process, an electrochemical process, or a combined electrochemical process of an electrochemical process and a mechanical polishing process.

According to a second aspect of the present invention, there is provided a method of polishing a substrate having a metal film formed thereon by pressing the substrate against a polishing surface. According to the polishing method, the substrate is initially polished to remove a native oxide of the metal film. The substrate is subsequently polished to remove the metal film of the substrate. According to this polishing method, without great modification of a conventional polishing apparatus, the metal film of the substrate can be polished in a state such that the native oxide of the metal film has been removed. Accordingly, uniform planarization of the substrate can be achieved.

In this case, the substrate may be pressed against the polishing surface under a first pressure during the initial polishing process and under a second pressure, different than the first pressure, during the subsequent polishing process. It is desirable that the first pressure is larger than the second pressure. According to this method, it is not necessary to change types of slurry during polishing, and hence a polishing process can continuously be performed.

Further, a first polishing liquid may be supplied to the polishing surface during the initial polishing process, and a second polishing liquid different than the first polishing liquid may be supplied to the polishing surface during the subsequent polishing process.

Water may be supplied to the polishing surface between the initial polishing process and the subsequent polishing process while the substrate is pressed against the polishing surface. When polishing pressures (pressures to press the substrate against the polishing surface) are changed between the initial polishing process and the subsequent polishing process, an increase of the temperature of the substrate may be caused by the polishing pressure in the initial polishing process. When the water supply process is performed between the initial polishing process and the subsequent polishing process, the temperature of the substrate can be decreased at the processing points. Accordingly, the subsequent polishing process can be performed more precisely. Further, even if polishing liquids are changed between the initial polishing process and the subsequent polishing process, the water supply process can reduce the amount of a polishing liquid remaining on the polishing surface which has been used in the initial polishing process and minimize an adverse influence on polishing properties of the polishing liquid used in the subsequent polishing process.

An endpoint of the initial polishing process may be detected based on a frictional force produced between the substrate and the polishing surface. In this case, the initial polishing process can be finished at proper timing, and the subsequent polishing process can be started at proper timing. Accordingly, good planarization properties can be achieved.

According to a third aspect of the present invention, there is provided a method of polishing a substrate having a metal film formed thereon by pressing the substrate against a polishing surface. According to the polishing method, the substrate is initially polished by pressing the substrate against the polishing surface under a first pressure. Water is supplied to the polishing surface after the initial polishing process while the substrate is pressed against the polishing surface. The substrate is subsequently polished by pressing the substrate against the polishing surface under a second pressure different than the first pressure after the supplying process.

When the polishing pressure is increased, the temperature of the substrate is likely to be increased at processing points. If the increased temperature of the substrate exceeds a certain limitation, the temperature of the substrate is unlikely to be decreased even though the polishing pressure is lowered during the subsequent polishing process. Thus, polishing properties of the polishing liquid (slurry) are deteriorated because of deterioration of an oxidizing agent in the slurry. Accordingly, a lowered polishing rate or an adverse influence on the polishing performance may be caused during the subsequent polishing process. According to the above polishing method, the supply of the polishing liquid (slurry) is stopped between the initial polishing process and the subsequent polishing process, and the substrate is polished while water is supplied to the polishing surface. This water supply process can decrease the temperature of the substrate at the processing points. Accordingly, the subsequent polishing process can be performed more precisely.

According to a fourth aspect of the present invention, there is provided a substrate processing apparatus for processing a substrate having a metal film formed thereon. The substrate processing apparatus has a process unit configured to remove a native oxide of the metal film formed on a surface of the substrate. The substrate processing apparatus also has a planarization unit configured to planarize the metal film of the substrate.

The process unit may comprise a wet process unit configured to dissolve the native oxide of the metal film in a chemical liquid or a dry process unit configured to reduce or etch the native oxide of the metal film with a gas. The planarization unit may comprise a chemical mechanical polishing unit configured to polish the metal film of the substrate by chemical mechanical polishing, an electrochemical process unit configured to perform an electrochemical process on the metal film of the substrate, or a combined electrochemical process unit configured to perform a combined electrochemical process, which includes an electrochemical process and a mechanical polishing process, on the metal film of the substrate.

The above and other objects, features, and advantages of the present invention will be apparent from the following description when taken in conjunction with the accompanying drawings which illustrate preferred embodiments of the present invention by way of example.

### BRIEF DESCRIPTION OF THE DRAWINGS

FIG. 1 is a plan view showing a polishing apparatus as a substrate processing apparatus according to a first embodiment of the present invention;

FIG. 2 is a vertical cross-sectional view showing a wet etching unit in the polishing apparatus shown in FIG. 1;

FIG. 3 is a vertical cross-sectional view showing a top ring which can adjust pressing forces to a plurality of areas of a wafer;

FIG. 4 is a plan view showing a polishing apparatus as a substrate processing apparatus according to a second embodiment of the present invention;

FIG. 5 is a graph showing an effect of a water supply process performed in a polishing method according to the present invention;

FIG. 6 is a schematic view showing a polishing unit which can detect a torque applied to a polishing table to detect a frictional force between a wafer and a polishing surface during polishing;

FIG. 7 is a flow chart showing an example of a polishing method according to the present invention;

FIG. 8 is a graph showing changes of the temperature of a polishing pad and a motor current in a polishing method according to the present invention;

FIG. 9 is a graph showing changes of the temperature of a polishing pad and a motor current in a polishing method according to the present invention;

FIG. 10 is a schematic view showing an eddy-current sensor for measuring the film thickness of a surface of a wafer by using an eddy current;

FIG. 11 is a schematic view showing a polishing unit having an optical sensor for measuring the film thickness of a surface of a wafer;

FIG. 12 is a flow chart showing an example of a polishing method according to the present invention;

FIG. 13 is a flow chart showing an example of a polishing method according to the present invention;

FIG. 14 is a flow chart showing an example of a polishing method according to the present invention;

FIG. 15 is a flow chart showing an example of a polishing method according to the present invention;

FIG. 16 is a plan view showing a polishing apparatus as a substrate processing apparatus according to a third embodiment of the present invention;

FIG. 17 is a plan view showing an example of an electrochemical process unit in a substrate processing apparatus according to a fourth embodiment of the present invention;

FIG. 18 is a plan view showing an example of a combined electrochemical process unit in a substrate processing apparatus according to a fifth embodiment of the present invention; and

FIG. 19 is a vertical cross-sectional view of FIG. 18.

### DETAILED DESCRIPTION OF THE PREFERRED EMBODIMENTS

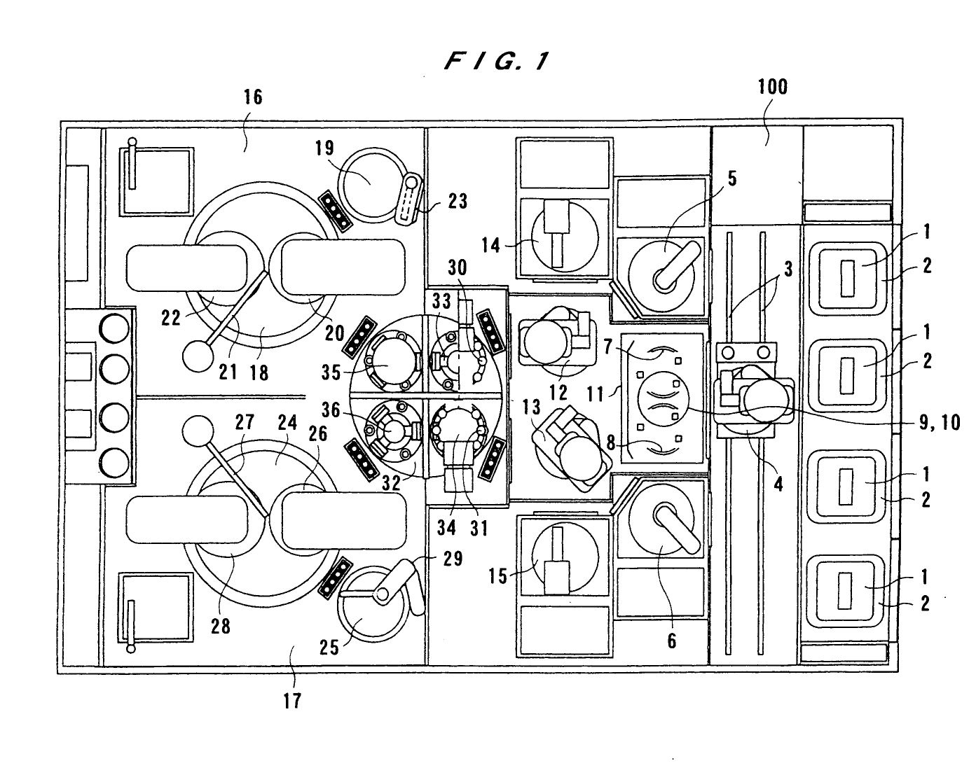

Embodiments of a substrate processing apparatus according to the present invention will be described below with reference to FIGS. 1 through 19. Like or corresponding parts are denoted by like or corresponding reference numerals throughout drawings, and will not be described below repetitively.

FIG. 1 is a plan view showing a polishing apparatus as a substrate processing apparatus according to a first embodiment of the present invention. As shown in FIG. 1, the polishing apparatus has four loading/unloading stages 2 on which wafer cassettes 1 are placed. Each of the wafer cassettes 1 stocks a large number of semiconductor wafers therein. The polishing apparatus includes a moving mechanism 3 arranged along an array of the loading/unloading stages 2. The moving mechanism 3 includes a first transfer robot 4 having two hands. Further, the polishing apparatus has a film thickness measurement unit 100 adjacent to the moving mechanism 3. The first transfer robot 4 is accessible to each of the wafer cassettes 1 placed on the loading/unloading stages 2 and to the film thickness measurement unit 100.

The polishing apparatus also includes two cleaning and drying devices 5 and 6 disposed at an opposite side of the moving mechanism 3 to the wafer cassettes 1. The hands of the first transfer robot 4 are accessible to the cleaning and drying devices 5 and 6. Each of the cleaning and drying devices 5 and 6 has a spin-drying function to dry a wafer by high-speed rotation. The polishing apparatus has a wafer station 11 disposed between the two cleaning and drying devices 5 and 6. The wafer station 11 includes four wafer stages 7, 8, 9, and 10. The hands of the first transfer robot 4 are also accessible to the wafer station 11.

The polishing apparatus has a second transfer robot 12 having two hands, which are accessible to the cleaning and drying device 5 and the three wafer stages 7, 9, and 10. The polishing apparatus also has a third transfer robot 13 having two hands, which are accessible to the cleaning and drying device 6 and the three wafer stages 8, 9, and 10. The wafer stage 7 is used to transfer a semiconductor wafer between the first transfer robot 4 and the second transfer robot 12. The wafer stage 8 is used to transfer a semiconductor wafer between the first transfer robot 4 and the third transfer robot 13. The wafer stage 9 is used to transfer a semiconductor wafer from the second transfer robot 12 to the third transfer robot 13. The wafer stage 10 is used to transfer a semiconductor wafer from third transfer robot 13 to the second transfer robot 12. The wafer stage 9 is located above the wafer stage 10.

The polishing apparatus includes a wet process unit 14 disposed adjacent to the cleaning and drying device 5. The hands of the second transfer robot 12 are accessible to the wet process unit 14. In the present embodiment, the wet process unit 14 comprises a wet etching unit for dissolving and removing a native oxide of the metal film formed on a surface of a substrate such as a semiconductor wafer by etching. The polishing apparatus also includes a cleaning device 15 adjacent to the cleaning and drying device 6 for cleaning a polished wafer. The hands of the third transfer robot 13 are accessible to the cleaning device 15.

As shown in FIG. 1, the polishing apparatus has two polishing units 16 and 17 as planarization units for planarizing a metal film of a substrate. Each of the polishing units 16 and 17 includes two polishing tables and a top ring for holding a wafer and pressing the wafer against the polishing tables. Specifically, the polishing unit 16 includes a first polishing table 18, a second polishing table 19, a top ring 20, a polishing liquid supply nozzle 21 for supplying a polishing liquid onto the first polishing table 18, a first dresser 22 for dressing the first polishing table 18, and a second dresser 23 for dressing the second polishing table 19. The polishing unit 17 includes a first polishing table 24, a second polishing table 25, a top ring 26, a polishing liquid supply nozzle 27 for supplying a polishing liquid onto the first polishing table 24, a first dresser 28 for dressing the first polishing table 24, and a second dresser 29 for dressing the second polishing table 25.

Further, the polishing unit 16 includes a reversing machine 30 for reversing a semiconductor wafer. The hand of the second transfer robot 12 is accessible to the reversing machine 30 and transfers a semiconductor wafer to the reversing machine 30. The polishing unit 17 includes a reversing machine 31 for reversing a semiconductor wafer. The hand of the third transfer robot 13 is accessible to the reversing machine 31 and transfers a semiconductor wafer to the reversing machine 31.

The polishing apparatus has a rotary transporter 32 disposed below the reversing machines 30 and 31 and the top rings 20 and 26. The rotary transporter 32 serves to transfer a wafer between the reversing machines 30 and 31 and the top rings 20 and 26. The rotary transporter 32 has four stages arranged at angular equal intervals for holding a wafer. Thus, the rotary transporter 32 is configured to simultaneously hold a plurality of wafers. The rotary transporter 32 also includes lifters 33 and 34 provided below the reversing machines 30 and 31, and pushers 35 and 36 provided near the top rings 20 and 26. When the center of the stage of the rotary transporter 32 is aligned with the center of a wafer chucked by the reversing machine 30 or 31, the lifter 33 or 34 is moved upward to transfer the wafer to the rotary transporter 32.

When the rotary transporter 32 is rotated, the wafer on the stage of the rotary transporter 32 is transferred to below the top ring 20 or 26, which has been swung above the rotary transporter 32. When the center of the top ring 20 or 26 is aligned with the center of the wafer on the rotary transporter 32, the pusher 35 or 36 is moved upward to transfer the wafer from the rotary transporter 32 to the top ring 20 or 26.

The wafer transferred to the top ring 20 or 26 is attracted by a vacuum attraction mechanism of the top ring 20 or 26. The wafer is transferred to the first polishing table 18 or 24 while it is attracted by the vacuum attraction mechanism. Then, the wafer is polished by a polishing surface such as a polishing pad or a grinding wheel attached to the first polishing table 18 or 24. The second polishing tables 19 and 25 are located at positions to which the top rings 20 and 26 can be moved, respectively. After the wafer is polished on the first polishing table 18 or 24, the wafer can further be polished on the second polishing table 19 or 25. The polished wafer is returned to the reversing machine 30 or 31 on the same route as described above.

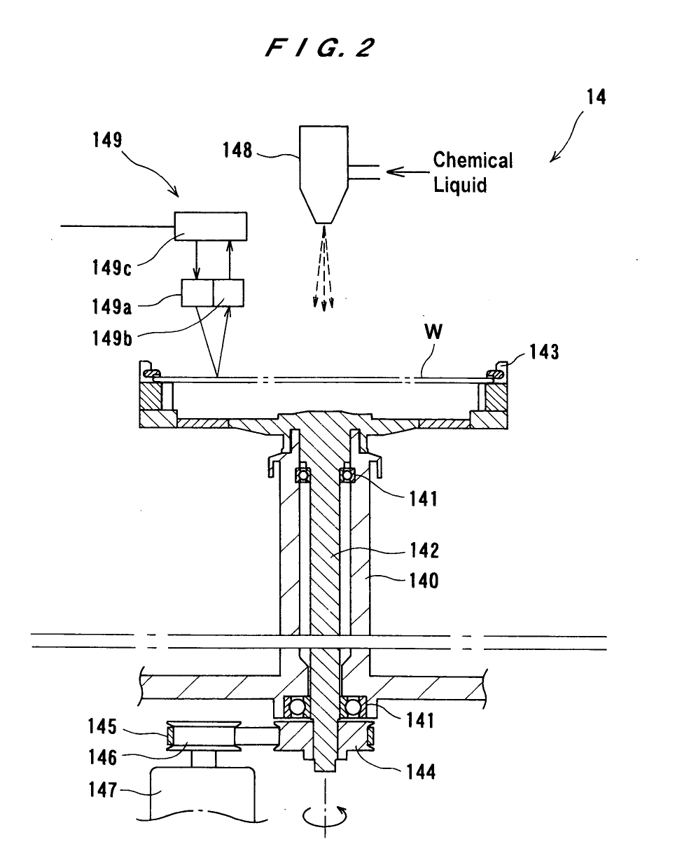

FIG. 2 is a vertical cross-sectional view showing the wet etching unit 14 in the polishing apparatus shown in FIG. 1. As shown in FIG. 2, the wet etching unit 14 has a cylinder 140, a rotation member 142 rotatable via bearings 141 inside of the cylinder 140, and chucking members 143 provided at an upper portion of the rotation member 142. The chucking members 143 serve to clamp a peripheral portion of a wafer W. The rotation member 142 has a pulley 144 attached to a lower end of the rotation member 142. The pulley 144 is coupled via a belt 145 and a pulley 146 to a motor 147. Thus, the rotation member 142 is rotated when the motor 147 is rotated. Accordingly, the wafer W held by the chucking members 143 is rotated. The chucking members 143 may comprise a centrifugal chucking mechanism for holding a wafer by centrifugal forces due to rotation or a pin chucking mechanism.

The wet etching unit 14 has a chemical liquid/pure water nozzle 148 disposed above the rotation member 142. The chemical liquid/pure water nozzle 148 jets a chemical liquid to etch a native oxide of a metal film formed on a surface of the wafer W or pure water onto the wafer W. The chemical liquid may include an acid chemical liquid or a chelating agent solution for forming a soluble complex. When a metal film of copper is formed on the substrate, the chemical liquid may include inorganic acids such as hydrofluoric acid, sulfuric acid, hydrochloric acid, and phosphoric acid, organic acids such as formic acid, acetic acid, propionic acid, oxalic acid, malonic acid, succinic acid, and malic acid, halide, carboxylic acid, salt of carboxylic acid, or a chelating agent solution for forming a soluble complex, for example, an alkali solution of amino acid such as ammonia, ethylene diamine tetraacetic acid (EDTA), or glycine. Mixture of these chemicals may also be used. When a chemical liquid is unlikely to spread over the entire surface of the wafer W because of a poor wettability of the surface of the wafer W, a surface active agent may be added into the chemical liquid to improve the wettability of the wafer W and the efficiency of the process.

At the time of etching, the chemical liquid is supplied from the chemical liquid/pure water nozzle 148 to the center and its vicinity of the wafer W. The chemical liquid flows toward the peripheral portion of the wafer W because of centrifugal forces due to rotation of the wafer W, so that the chemical liquid can spread over the entire surface of the wafer W. The chemical liquid may not be supplied to portions of the wafer W with which the chucking members 143 are brought into contact. In the case of the centrifugal chucking mechanism, the rotational speed of the rotation member 142 may temporarily be increased or decreased to increase or decrease centrifugal forces so that the wafer W slides with respect to the chucking members 143. Thus, portions of the wafer W with which the chucking members 143 are brought into contact are changed to thereby supply the chemical liquid to the entire area of the wafer W.

After the native oxide of the metal film is etched, a switching controller (not shown) switches sources of the chemical liquid/pure water nozzle 148 so as to supply pure water from the chemical liquid/pure water nozzle 148 to the wafer W. The wafer W is rinsed and cleaned with pure water so as to remove a chemical liquid remaining on the wafer W. The supply of a chemical liquid to the wafer W is not limited to the use of the nozzle shown in FIG. 2. For example, the wafer W may be immersed in a chemical liquid. Alternatively, a chemical liquid may be supplied by various chemical liquid application devices which have widely been employed for processing a substrate. Such chemical liquid application devices include a roll-type application device, a spray-type application device, and a spin-type application device.

As shown in FIG. 2, the wet etching unit 14 includes a film thickness measurement device 149′ disposed above the rotation member 142. The film thickness measurement device 149 has a light-emitting section 149a, a light-receiving section 149b, and an arithmetic unit 149c. The film thickness measurement device 149 is connected to a swing mechanism (not shown) for swinging the film thickness measurement device 149. Thus, the film thickness measurement device 149 is configured to emit light from the light-emitting section 149a to the entire surface of the wafer W. With the film thickness measurement device 149 having the above arrangement, light reflected from the wafer W is analyzed to measure the film thickness of the wafer W during etching (in-situ measurement) and detect an endpoint of the etching process.

The light-emitting section 149a of the film thickness measurement device 149 may emit light having a short wavelength or light having a plurality of wavelengths. In the present embodiment, the film thickness measurement device 149 comprises an optical device. However, the film thickness measurement device 149 may comprise an eddy-current sensor, which supplies an AC signal to a sensor coil to generate an eddy current in a metal film including a native oxide and detects the eddy current by the sensor coil of a detection circuit. In this case, the sensor coil may be disposed near an upper surface of the wafer W, on which circuits are formed, or near a lower surface of the wafer.

The film thickness measurement unit 149 can obtain a film thickness distribution over the surface of the wafer W, particularly measurement data of a film thickness distribution in a radial direction of the wafer W. In this case, the measurement data can be fed back to the polishing unit 16 or 17 so as to optimize polishing rates in the radial direction of the wafer W during polishing. For example, forces for the top ring 20 or 26 to press the wafer W are adjusted to be higher at areas having a relatively larger film thickness. Thus, polishing rates can be set independently for each area in the radial direction so as to achieve a high within wafer uniformity.

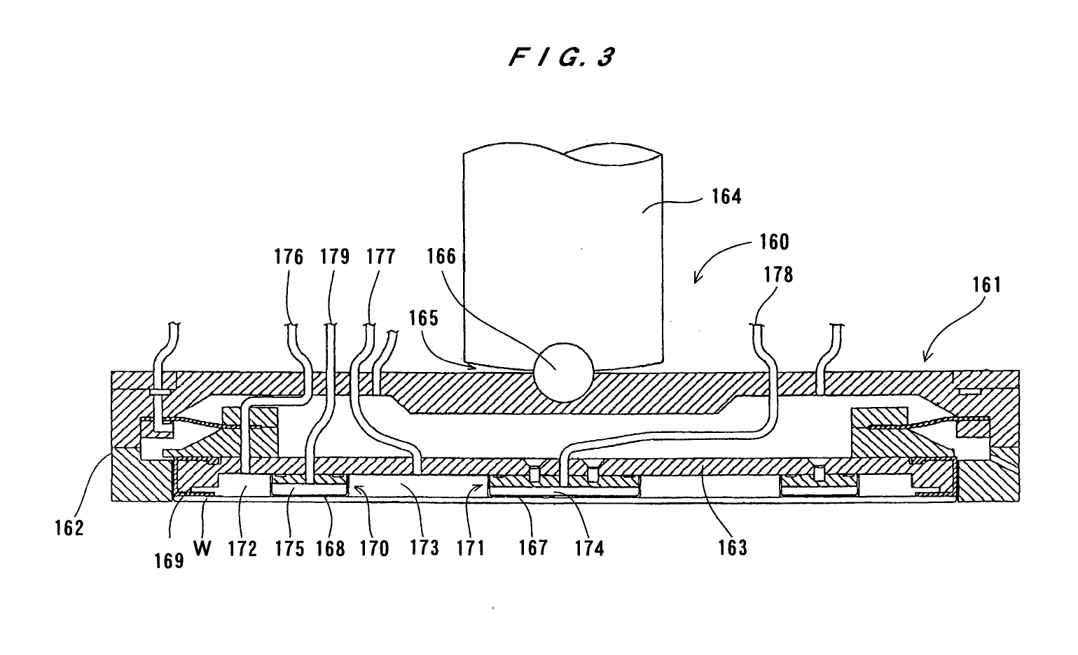

FIG. 3 is a cross-sectional view showing a top ring 160 which can adjust pressing forces to a plurality of areas of a wafer W. As shown in FIG. 3, the top ring 160 includes a top ring body 161, a retainer ring 162 provided at a lower end of a periphery of the top ring body 161, and a chucking plate 163 which is vertically movable with respect to the top ring body 161. The top ring body 161 is connected to a top ring shaft 164 via a universal joint 165. The universal joint 165 includes a ball bearing mechanism having a ball 166 for supporting the top ring body 161 at a lower end of the top ring shaft 164 so as to allow the top ring body 161 to be tilted with respect to the top ring shaft 164, and a rotation transmitting mechanism (not shown) for transmitting rotation of the top ring shaft 164 to the top ring body 161.

The top ring 160 has a wafer holding section which can control a profile of the wafer W by a plurality of elastic membranes 167 and 168 provided at a lower surface of the chucking plate 163. Specifically, the wafer holding section is divided into a plurality of pressure chambers 172 and 173 by a seal ring 169, an annular ring tube 170, and a circular central bag 171. The seal ring 169 is brought into contact with a peripheral portion of the wafer W so as to seal an internal space located above the wafer W The ring tube 170 is disposed in the internal space located above the wafer W. The central bag 171 has a pressure chamber 174 formed therein, and the ring tube 170 has a pressure chamber 175 formed therein.

The pressure chambers 172 to 175 are connected to fluid passages 176 to 179, respectively, so as to adjust pressures of fluids to be supplied to the pressure chambers 172 to 175. Accordingly, it is possible to control forces for the pressure chambers 172 to 175 to press the wafer W independently of each other. Thus, polishing rates can be controlled independently at portions corresponding to the pressure chambers 172 to 175.

There will be described polishing operation of the polishing apparatus. First, a wafer to be polished is housed in a wafer cassette 1 in a state such that a surface on which a metal film is formed faces upward. The wafer cassette 1 having a large number of wafers is placed on the loading/unloading stage 2. The first transfer robot 4 takes out one wafer from the wafer cassette 1 and transfers it to the wafer stage 7. The wafer to be transferred to the wafer stage 7 may be transferred to the film thickness measurement unit 100 to measure the film thickness of a native oxide formed on the surface of the wafer. In this case, time required for etching a native oxide having the measured film thickness may be calculated by a controller (or database) in the polishing apparatus to properly set an etching time of the native oxide in the subsequent wet etching unit 14.

The wafer placed on the wafer stage 7 is then transferred to the wet etching unit 14 by the second transfer robot 12. In the wet etching unit 14, a chemical liquid for etching a native oxide is supplied from the chemical liquid/pure water nozzle 148 (see FIG. 2) to the wafer, so that the native oxide on the metal film of the wafer is dissolved and removed by the chemical liquid. When the etching process of the native oxide of the metal film is completed, the supply from the chemical liquid/pure water nozzle 148 is switched from the chemical liquid to pure water. Thus, the wafer is rinsed and cleaned with pure water to remove a chemical liquid remaining on the wafer.

The second transfer robot 12 takes out the etched wafer from the wet etching unit 14 and transfers it to the reversing machine 30. In the reversing machine 30, the wafer is reversed so that the surface on which the metal film is formed faces downward. Then, the wafer is transferred to the rotary transporter 32. After the rotary transporter 32 receives the wafer, it rotates through 90° and transfer the wafer to the pusher 35. The wafer on the pusher 35 is attracted by the top ring 20 of the polishing unit 16, moved to the first polishing table 18, and polished on the first polishing table 18. As described above, the wafer may be polished on the second polishing table 25 after polishing on the first polishing table 18.

The polished wafer is transferred from the pusher 35 to the rotary transporter 32. After the rotary transporter 32 receives the wafer, it rotates through 180° and transfer the wafer to the reversing machine 31. In the reversing machine 31, the wafer is reversed so that the surface on which the metal film is formed faces upward. Then, the wafer is transferred to the third transfer robot 13. The third transfer robot 13 transfers the wafer to the cleaning device 15, where the wafer is cleaned. The third transfer robot 13 takes out the cleaned wafer from the cleaning device 15 and introduces it into the cleaning and drying device 6, where the wafer is rinsed and dried. The dried wafer is returned to the wafer cassette 1 by the first transfer robot 4.

In the present embodiment, the polishing apparatus has two cleaning and drying devices 5 and 6, one wet etching unit 14, and one cleaning device 15. However, the present invention is not limited to such configuration. For example, the polishing apparatus may have one cleaning and drying device, one etching unit, and two cleaning devices. Alternatively, the polishing apparatus may have two cleaning and drying devices, one etching unit, and one cleaning device. The polishing apparatus may have one cleaning and drying device, two etching units, and one cleaning device.

Further, the wet etching unit 14 is provided as a separate unit from the polishing units 16 and 17. However, the aforementioned wet etching mechanism may be incorporated into the polishing unit 16 or 17. Alternatively, a proper chemical liquid can be selected from chemical liquids that can be used in the aforementioned etching process, and supplied onto the polishing table 18 or 24 from the polishing liquid supply nozzle 21 or 27 of the polishing unit 16 or 17 to perform an etching process in the polishing unit 16 or 17. In this case, since a polishing process can be performed immediately after the etching process, development of a native oxide can be prevented after the chemical liquid process. Thus, it is desirable to perform a polishing process immediately after a chemical liquid process to minimize development of a native oxide. If a chemical liquid used to dissolve and remove a native oxide of a metal film has an adverse influence on polishing performance of slurry used in a polishing process, then the wafer should be rinsed with ultrapure water or the like after the chemical liquid process.

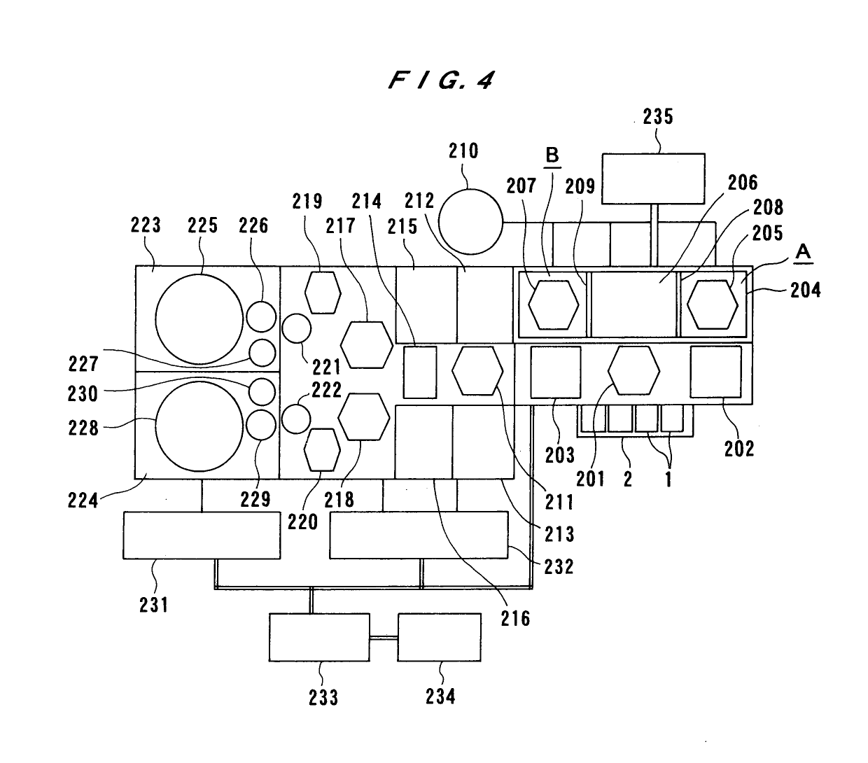

FIG. 4 is a plan view showing a polishing apparatus as a substrate processing apparatus according to a second embodiment of the present invention. As shown in FIG. 4, the polishing apparatus has a loading/unloading stage 2 on which wafer cassettes 1 are placed, a first transfer robot 201 having a hand accessible to the wafer cassettes 1, wafer stages 202 and 203 provided on both sides of the first transfer robot 201, and a vacuum chamber 204 arranged along an array of the first transfer robot 201 and the wafer stages 202 and 203.

The vacuum chamber 204 houses a dry process unit 206, a second transfer robot 205 having a hand accessible to the wafer stage 202, and a third transfer robot 207 having a hand accessible to the wafer stage 203. In the present embodiment, the dry process unit 206 comprises a dry etching unit for reducing or etching a native oxide of a metal film formed on a surface of a wafer. The vacuum chamber 204 includes a shutter 208 disposed between the second transfer robot 205 and the dry etching unit 206, and a shutter 209 disposed between the third transfer robot 207 and the dry etching unit 206. The second transfer robot 205 is disposed in a robot chamber A, and the third transfer robot 207 is disposed in a robot chamber B. These robot chambers A and B are connected to a vacuum pump 210 so as to serve as load locks. The dry etching unit 206 is also connected to the vacuum pump 210.

The vacuum chamber 204 also has a shutter (not shown) disposed between the wafer stage 202 and the second transfer robot 205, which is used to transfer a wafer from the wafer stage 202 to the second transfer robot 205, and a shutter (not shown) disposed between the wafer stage 203 and the third transfer robot 207, which is used to transfer a wafer from the third transfer robot 207 to the wafer stage 203.

The polishing apparatus includes a fourth transfer robot 211 disposed at a position accessible to the wafer stage 203, two cleaning and drying devices 212 and 213 disposed on both sides of the fourth transfer robot 211, a wafer stage 124 disposed adjacent to the fourth transfer robot 211, and two cleaning devices 215 and 216 disposed on both sides of the wafer stage 124. The cleaning and drying devices 212 and 213 have the same functions as the cleaning and drying devices 5 and 6 in the first embodiment. The fourth transfer robot 211 has a hand accessible to the cleaning and drying devices 212 and 213, the wafer stage 124, and the cleaning devices 215 and 216.

The polishing apparatus also includes a fifth transfer robot 217 having two hands accessible to the cleaning device 215 and the wafer stage 214, a sixth transfer robot 218 having two hands accessible to the cleaning device 216 and the wafer stage 214, a reversing machine 219 disposed at a position which the hands of the fifth transfer robot 217 can reach, and a reversing machine 220 disposed at a position which the hands of the sixth transfer robot 218 can reach. The polishing apparatus has transporters 221 and 222 so as to correspond to the reversing machines 219 and 220, respectively.

The polishing apparatus includes polishing units 223 and 224 adjacent to the transporters 221 and 222, respectively. The polishing unit 223 has a polishing table 225, a top ring 226, and a pusher 227. The polishing unit 224 has a polishing table 228, a top ring 229, and a pusher 230. In the present embodiment, as shown in FIG. 4, the polishing apparatus has a slurry supply unit 231 for supplying slurry to the polishing tables 225 and 228 in the polishing units 223 and 224, a chemical liquid/pure water supply unit 232, a controller 233 for controlling the polishing apparatus, and a monitor 234 for monitoring operational conditions of the polishing apparatus.

The dry etching unit 206 in the vacuum chamber 204 can reduce or etch a native oxide on a surface of a wafer with a process gas. As shown in FIG. 4, the dry etching unit 206 is connected to a process gas supply unit 235. For example, in the dry etching unit 206, a mixed gas of hydrogen and argon may be used as a process gas, and hydrogen plasma generated by electron cyclotron resonance (ECR) may be applied to a surface of a wafer to etch a native oxide on the surface of the wafer. Depending upon properties of a process gas to be used, a surface of a wafer may be etched by reactive ion etching (RIE) or by magnetically enhanced reactive ion etching (MERIE). Instead of hydrogen, ammonia or the like can also be used as a process gas. Alternatively, the dry etching unit 206 may have a heating treatment chamber for heating hydrogen, ammonia, or organic acid such as formic acid or acetic acid to several hundreds degrees centigrade to form a reducing atmosphere therein to thereby reduce and remove a native oxide of a surface of a wafer.

There will be described polishing operation of the polishing apparatus. First, a wafer to be polished is housed in a wafer cassette 1 in a state such that a surface on which a metal film is formed faces upward. The wafer cassette 1 having a large number of wafers is placed on the loading/unloading stage 2. The first transfer robot 201 takes out one wafer from the wafer cassette 1 and transfers it to the wafer stage 202. The shutter between the wafer stages 202 and the second transfer robot 205 is opened, and the second transfer robot 205 introduces the wafer placed on the wafer stage 202 into the robot chamber A in the vacuum chamber 204.

After the wafer is transferred into the robot chamber A, the vacuum pump 210 is operated so as to evacuate the robot chamber A, the dry etching unit 206, and the robot chamber B. After the robot chamber A is evacuated, the shutter 208 between the robot chamber A and the dry etching unit 206 is opened. Then, the second transfer robot 205 transfers the wafer into the dry etching unit 206. In the dry etching unit 206, dry etching using the aforementioned process gas is performed to reduce or etch a native oxide on the surface of the wafer.

When the dry etching is completed in the dry etching unit 206, the shutter 209 between the dry etching unit 206 and the third transfer robot 207 is opened. Then, the third transfer robot 207 introduces the wafer into the robot chamber B. Thereafter, the vacuum in the robot chamber B is released to atmosphere. Then, the shutter between the third transfer robot 207 and the wafer stage 203 is opened, and the third transfer robot 207 transfers the wafer to the wafer stage 203.

The fourth transfer robot 211 transfers the wafer placed on the wafer stage 203 to the wafer stage 214. The fifth transfer robot 217 transfers the wafer placed on the wafer stage 214 to the reversing machine 219. In the reversing machine 219, the wafer is reversed so that the surface on which the metal film is formed faces downward. Then, the wafer is transferred to the transporter 221. The wafer on the transporter 221 is transferred via the pusher 227 in the polishing unit 223 to the top ring 226, which attracts the wafer. The wafer is moved to the polishing table 225 and polished on the polishing table 225.

The polished wafer is transferred from the pusher 227 via the transporter 221 to the reversing machine 219. In the reversing machine 219, the wafer is reversed so that the surface on which the metal film is formed faces upward. Then, the wafer is transferred to the fifth transfer robot 217. The fifth transfer robot 217 transfers the wafer to the cleaning device 215, where the wafer is cleaned. The fourth transfer robot 211 takes out the cleaned wafer from the cleaning device 215 and introduces it into the cleaning and drying device 212, where the wafer is rinsed and dried. The fourth transfer robot 211 transfers the dried wafer to the wafer stage 203. The wafer placed on the wafer stage 203 is returned to the wafer cassette 1 by the first transfer robot 201.

After the dry etching process in the dry etching unit 206 and before the polishing process in the polishing unit 223, the wafer may be introduced into the cleaning device 215 or 216 and cleaned therein. Depending upon selection of cleaning processes, the wafer stage 203 and the fourth transfer robot 211 may be eliminated. In the present embodiment, the dry etching unit 206 is provided as a separate unit from the polishing units 223 and 224. However, the aforementioned dry etching mechanism may be incorporated into the polishing unit 223 or 224.

In the above embodiments, a native oxide is removed by a wet process using a chemical liquid or by a dry process using a gas. However, the native oxide may be removed by polishing in a polishing unit. Specifically, a first polishing process is performed under conditions suitable for polishing a native oxide of a metal film formed on a surface of a wafer to remove the native oxide. Then, a second polishing process is performed under conditions suitable for polishing the metal film on the surface of the wafer to remove the metal film of the wafer. According to this two-stage polishing process, without great modification of a conventional polishing apparatus, the metal film of the wafer can be polished in a state such that the native oxide of the metal film has been removed. Thus, uniform planarization can be achieved.

The metal film on the surface of the wafer may also be polished under the conditions for polishing the native oxide of the metal film. In such a case, in addition to the native oxide, the metal film may be polished to some extent in the first polishing process. If the first polishing process is excessively continued, insufficient polishing or an increased amount of dishing is caused to deteriorate planarization properties, particularly, in a case of formation of copper embedded interconnections. Accordingly, the second polishing process should be started at least before copper is completely removed.

For example, pressures to press the wafer against the polishing surface (i.e., polishing pressures) may be changed to perform the aforementioned two-stage polishing process. Generally, a native oxide is more unlikely to be polished than a metal film. Accordingly, for example, in a case of copper polishing, a first polishing process is performed under a high polishing pressure of at least about 17.225 kPa (2.5 psi), preferably in a range of about 17.225 kPa to about 27.56 kPa (about 2.5 psi to about 4.0 psi), to mainly remove the native oxide. Then, a second polishing process is performed under a low polishing pressure of at most about 10.335 kPa (1.5 psi), preferably in a range of about 10.335 kPa to about 3.445 kPa (about 1.5 psi to about 0.5 psi) to remove the metal film. Thus, when the polishing pressure in the first polishing process is larger than that in the second polishing process, the native oxide is mainly removed during the first polishing process while the metal film is removed during the second polishing process.

According to the above two-stage polishing process, without any separate process units other than a polishing unit, a metal film formed on a surface of a wafer can be polished in a state such that a native oxide on the metal film has been removed. Thus, uniform planarization can be achieved. Further, since it is not necessary to change types of slurry during polishing, a polishing process can continuously be performed.

When the polishing pressure is increased in the first polishing process, the temperature of the wafer is likely to be increased at processing points. If the increased temperature of the wafer exceeds a certain limitation, the temperature of the wafer is unlikely to be decreased even though the polishing pressure is lowered in the polishing process. Thus, polishing properties of slurry are deteriorated because of deterioration of an oxidizing agent in the slurry. Accordingly, a lowered polishing rate or an adverse influence on the polishing performance may be caused during the second polishing process. From this point of view, it is desirable to stop the supply of the polishing liquid (slurry) between the first polishing process and the second polishing process and to polish the substrate while water is supplied to the polishing surface. This water supply process can decrease the temperature of the wafer at the processing points. After the water supply process, the second polishing process is performed while a polishing liquid (slurry) is supplied to the polishing surface. In this case, the second polishing process can be performed more precisely.

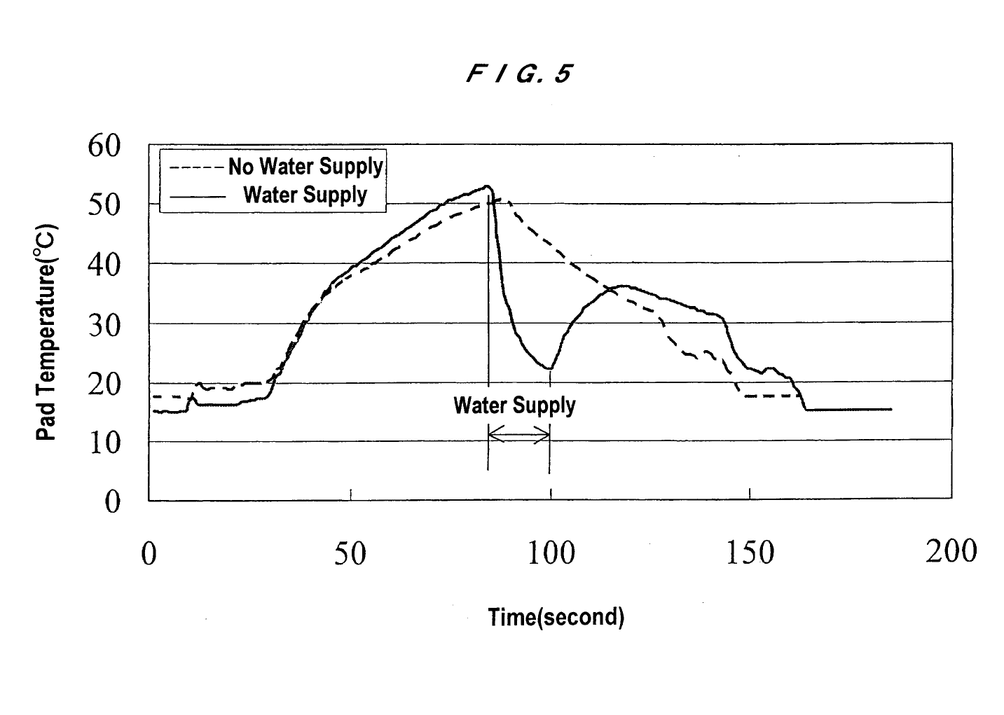

FIG. 5 is a graph showing the effect of the water supply process. In FIG. 5, the dashed line represents a case in which no water supply process was performed, and the solid line represents a case in which a water supply process was performed. As shown in FIG. 5, a water supply process performed between a first polishing process and a second polishing process could greatly lower the temperature of a polishing surface (polishing pad) and reduce the amount of dishing. In the example shown in FIG. 5, the amount of dishing was about 60 nm to about 75 nm without a water supply process, and about 40 nm to about 60 nm with a water supply process.

As another example of the two-stage polishing process, composition of a polishing liquid (slurry) to be supplied to the polishing surface may be changed. Specifically, the first polishing process may employ acidic slurry adjusted in pH, slurry from which an anticorrosive is removed, or slurry containing a chelating agent to from a soluble metal complex. The second polishing process may employ slurry which is used in a general polishing process. Thus, slurry suitable for removing a native oxide is used during the first polishing process. Then, the slurry suitable for removing a native oxide is changed into slurry for polishing the metal film during the second polishing process.

According to this two-stage polishing process, without any separate process units other than a polishing unit, a metal film formed on a surface of a wafer can be polished in a state such that a native oxide on the metal film has been removed. Thus, uniform planarization can be achieved.

In this case, the polishing slurry used in the first polishing process may have an adverse influence on polishing properties of the slurry used in the second polishing process. Accordingly, as in the case where polishing pressures are changed, it is desirable to stop the supply of the polishing liquid (slurry) between the first polishing process and the second polishing process and to supply water to the polishing surface. This water supply process can reduce the amount of slurry remaining on the polishing surface which has been used during the first polishing process and minimize an adverse influence on polishing properties of slurry used during the second polishing process.

In order to achieve good planarization, the first polishing process should be finished at proper timing and shifted into the second polishing process at proper timing. Accordingly, it is desirable to detect an endpoint of the first polishing process or properly set an endpoint of the first polishing process. The endpoint of the first polishing process can be detected or set as follows.

When the native oxide is polished and completely removed in the first polishing process, characteristics of the wafer change so that a frictional force between the wafer and the polishing surface is varied during polishing. Specifically, when a region of the metal film is polished after the uppermost native oxide has been polished, a change of a frictional force between the wafer and the polishing surface is caused by a difference in coefficient of friction between the materials. Accordingly, by detecting the frictional force, an endpoint of the first polishing process can be detected. For example, when a copper film is polished under a predetermined polishing pressure with usual slurry, the entire surface of the copper film is covered with an insoluble complex after the native oxide has completely be polished, so that a frictional force is dramatically increased in general. Accordingly, if the change of the frictional force is detected, it is possible to detect an endpoint of the first polishing process.

The frictional force between the wafer and the polishing surface is applied as a load torque to the rotating polishing table or top ring. Accordingly, it is possible to detect the frictional force by detecting a torque applied to the polishing table or top ring. When the polishing table or top ring is rotated by an electric motor, the torque can be detected by a current flowing through the motor. Thus, an endpoint of the first polishing process can be detected by monitoring a current flowing through the motor with an ammeter.

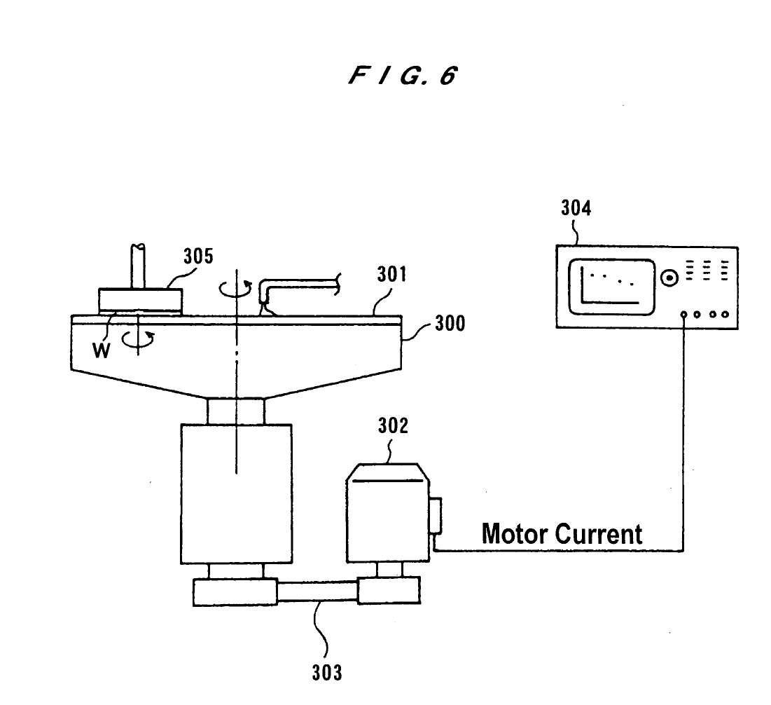

FIG. 6 is a schematic view showing a polishing unit which can detect a torque applied to a polishing table 300 to detect a frictional force between a wafer W and a polishing surface 301 during polishing. As shown in FIG. 6, the polishing unit has an electric motor 302 for rotating the polishing table 300. When the motor 302 is driven, the polishing table 300 is rotated via a belt 303. The motor 302 is connected to a current monitor 304 for detecting a current flowing through the motor 302 and performing signal processing. The current monitor 304 detects a current flowing through the motor 302 during polishing. The current monitor 304 measures variations of the current flowing through the motor 302 to detect changes of a torque applied to the polishing table 300. Accordingly, changes of a frictional force between the wafer W held by the top ring 305 and the polishing surface 301 can be detected. Thus, an endpoint of the first polishing process is detected.

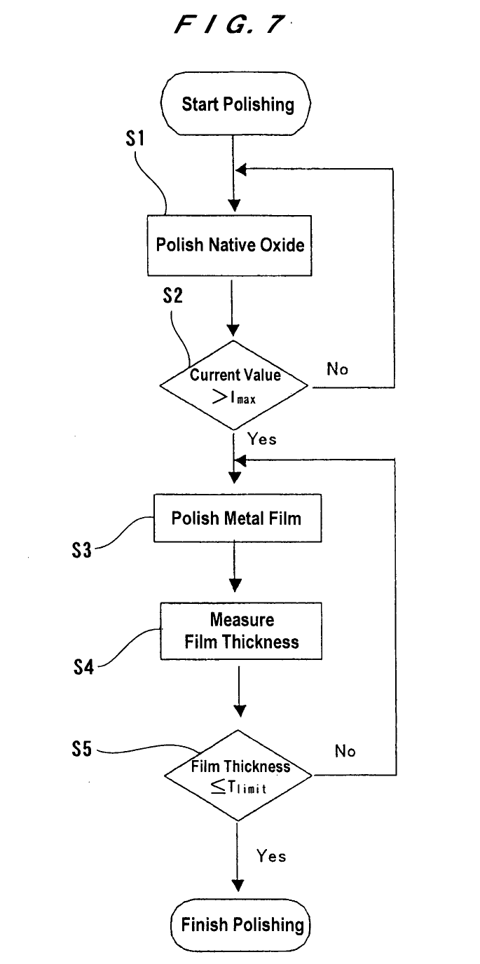

Specifically, a two-stage polishing process is performed as shown in FIG. 7. When a first polishing process is started to polish a native oxide of the wafer W (step S1), it is judged whether or not a current flowing through the motor 302 is larger than a predetermined current value (threshold value) Iₘₐₓ (step S2). The threshold value Iₘₐₓ may be inputted by an operator or set based on a database storing past data.

If the current measured by the current monitor 304 is not larger than the threshold value Iₘₐₓ, the first polishing process is continued. If the current measured by the current monitor 304 is larger than the threshold value Iₘₐₓ it is determined that the first polishing process reaches its endpoint, and a second polishing process is started to polish a metal film formed on the wafer W (step S3). During the second polishing process, the film thickness of the wafer W is measured by a film thickness measurement unit (not shown) (step S4). It is judged whether or not the measured film thickness is equal to or smaller than a predetermined film thickness (threshold value) Tₗᵢₘᵢₜ (step S5). The threshold value Tₗᵢₘᵢₜ may be inputted by an operator or set based on a database storing past data. If the measured film thickness is larger than the threshold value Tₗᵢₘᵢₜ, the second polishing process is continued. If the measured film thickness is not larger than the threshold value Tₗᵢₘᵢₜ, the second polishing process is finished.

In the example shown in FIG. 6, a current flowing through motor 302 for rotating the polishing table 300 is detected so as to detect a torque (frictional force) applied to the polishing table 300. However, a torque applied to the top ring 305 may be measured. Further, torques applied to the top ring 305 and the polishing table 300 may be measured. Furthermore, a frictional force between the top ring 305 and the polishing surface 301 on the polishing table 300 may directly be measured instead of detecting a current flowing through the motor 302. In any case, a proper measurement method of a frictional force can be selected according to polishing conditions including properties of the wafer W and a polishing liquid.

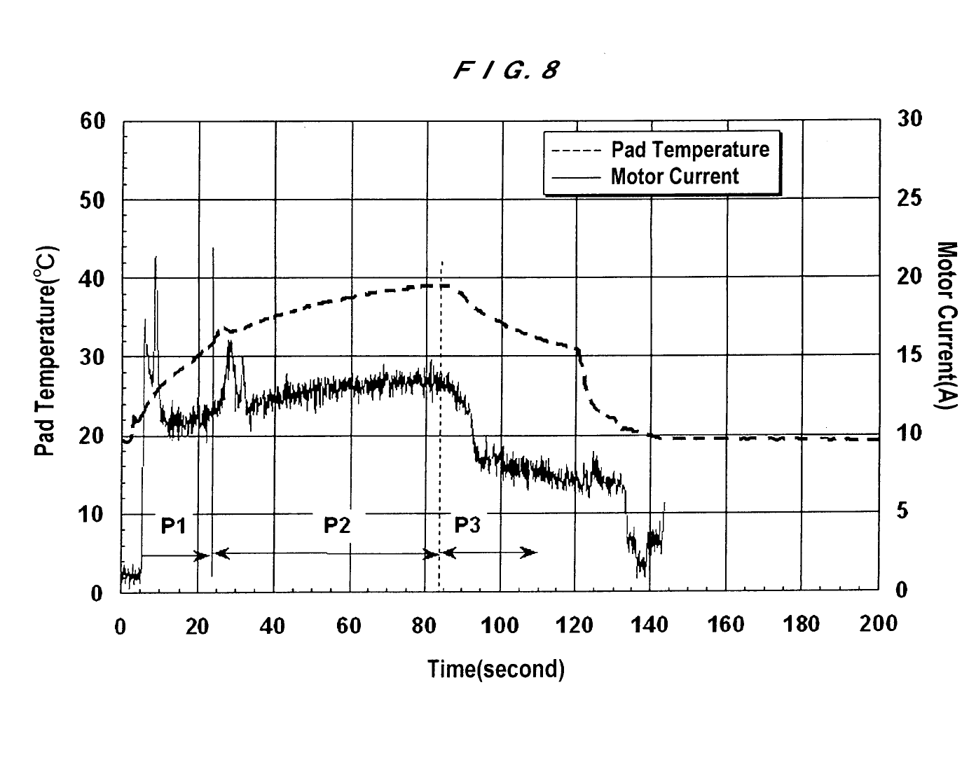

FIG. 8 is a graph showing changes of the temperature of a polishing pad (polishing surface) and a motor current in a case where a metal film was polished under a lowered polishing pressure after a native oxide was polished under a high polishing pressure. The dashed line represents the temperature of a polishing pad, and the solid line represents a motor current. In the example shown in FIG. 8, a first polishing process was performed under a polishing pressure P1 of 17.225 kPa (2.5 psi) to polish the native oxide. When a motor current became large, the polishing pressure was changed to P2 of 10.335 kPa (1.5 psi), and a second polishing process was started. In this example, the polishing pressure was further changed to P3 of 6.89 kPa (1.0 psi).

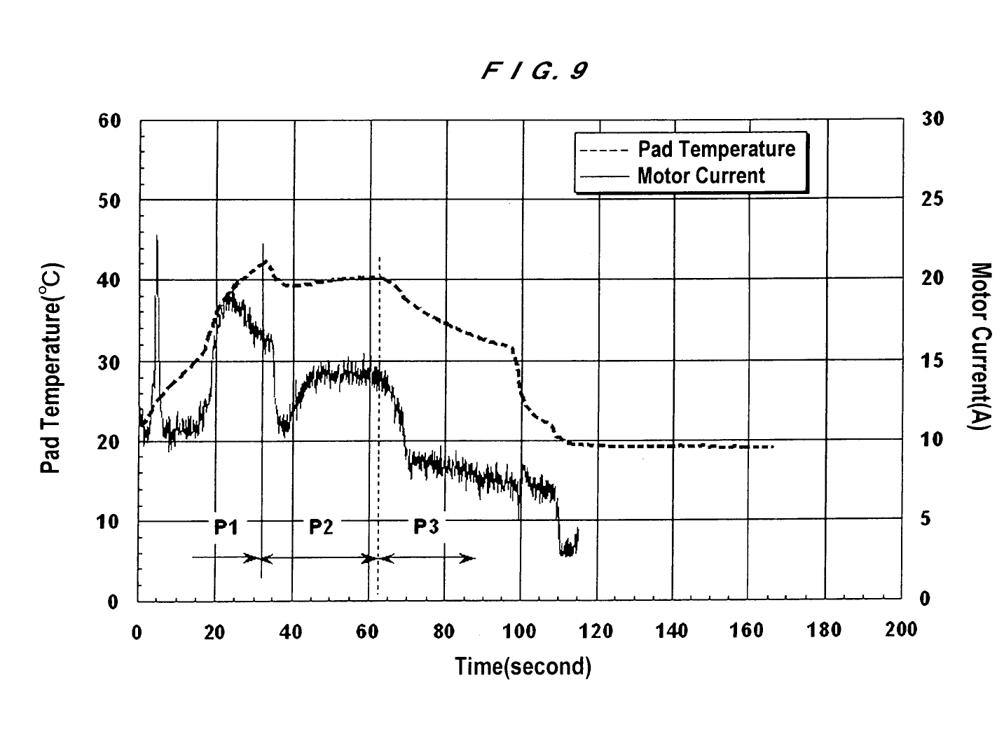

As shown in FIG. 8, a second polishing process may be started immediately after a change of a frictional force (motor current) is detected. However, as shown in FIG. 9, a first polishing process may be continued for a certain period of time after a change of a frictional force (motor current) is detected, and then a second polishing process may be started. The amounts of dishing were about 55 nm to about 60 nm in FIG. 8, and about 85 nm to about 90 nm in FIG. 9, respectively.

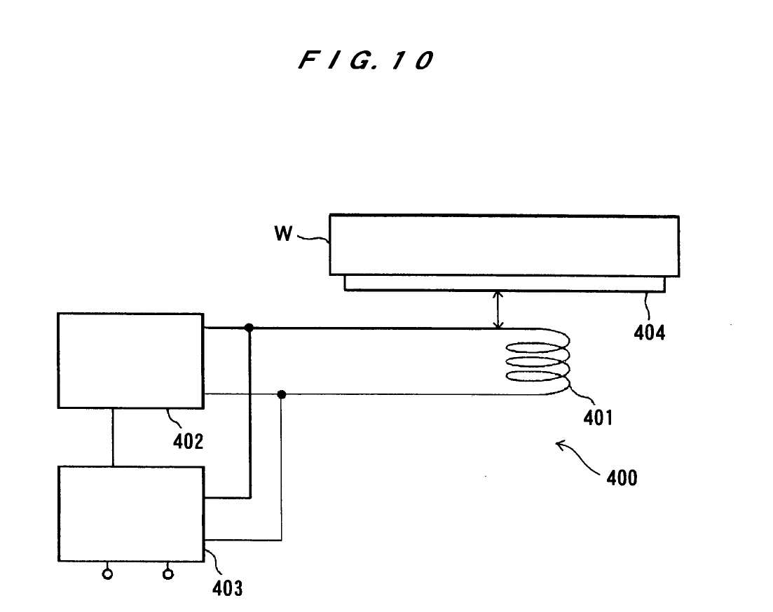

In order to detect an endpoint of the first polishing process, as shown in FIG. 10, an eddy-current sensor 400 may be used to measure the film thickness of a surface of a wafer W. An endpoint of the first polishing process may be detected based on the measured film thickness. The eddy-current sensor 400 has a sensor coil 401, an AC signal source 402 connected to the sensor coil 401, and a detection circuit 403 connected to the sensor coil 401 and the AC signal source 402. The sensor coil 401 is embedded in a polishing table and disposed near a metal film 404 of the wafer W, which contains a native oxide.

In the eddy-current sensor 400, the AC signal source 402 supplies AC signals to the sensor coil 401 to form an eddy current in the metal film 404 containing the native oxide. The detection circuit 403 detects an eddy current. The impedance of the detected eddy-current signal is separated into a resistance component and a reactance component. The film thickness of the metal film 404 formed on the surface of the wafer W is detected by measuring variations of the resistance component and the reactance component.

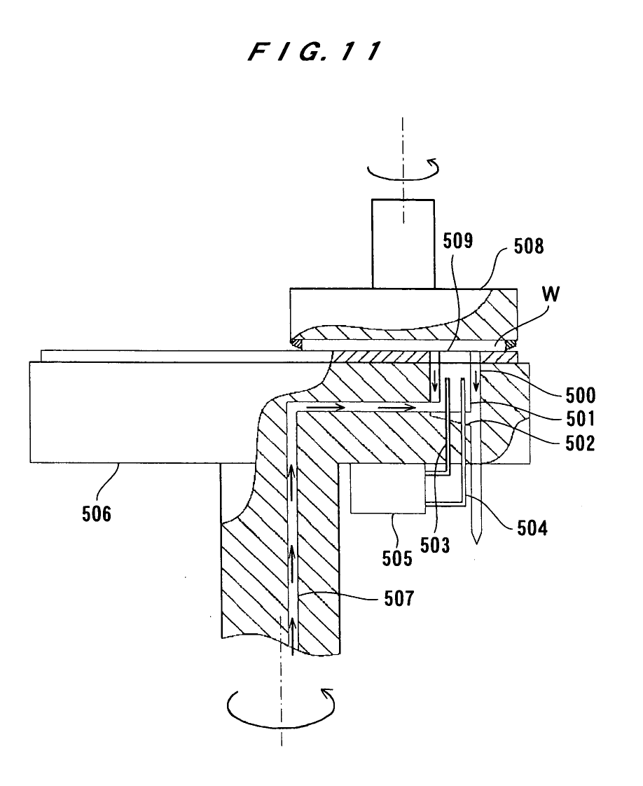

Further, as shown in FIG. 11, an optical sensor may be employed to detect an endpoint of the first polishing process. As shown in FIG. 11, the optical sensor includes a water jet nozzle 501 for jetting a columnar stream 500 to a wafer W, a water tray 502 for receiving the stream 500 jetted from the water jet nozzle 501, and a measurement arithmetic unit 505 having a light-emitting fiber 503 and a light-receiving fiber 504. The water jet nozzle 501 and the water tray 502 are formed within the polishing table 506. The light-emitting fiber 503 and the light-receiving fiber 504 have ends located within the water jet nozzle 501.

A pressurized stream is supplied through a stream pipe 507 to the water jet nozzle 501. Thus, a thin columnar stream 500 is jetted from a tip end of the water jet nozzle 501 to a surface of the wafer W to form a measurement spot 509 on the surface of the wafer W held by the top ring 508. In this state, light is emitted from the measurement arithmetic unit 505 through the light-emitting fiber 503 into the stream 500 and applied through the stream 500 to the measurement spot 509 on the wafer W. Reflected light from the measurement spot 509 is introduced through the stream 500 and the light-receiving fiber 504 into the measurement arithmetic unit 505, which detects the film thickness of the wafer W based on the reflected light. The optical sensor can receive reflected light having less noise because slurry attached onto the surface of the wafer W is cleaned by the stream 500.

The aforementioned monitors or sensors may be incorporated with each other to detect an endpoint of a first polishing process. For example, detection of the endpoint of the first polishing process may be performed by a combination of the current monitor and the eddy-current sensor, a combination of the current monitor and the optical sensor, a combination of the eddy-current sensor and the optical sensor, or a combination of the current monitor, the eddy-current sensor, and the optical sensor.

The film thickness of a native oxide formed on a wafer becomes larger in proportion to a stand-by time between a previous process of a polishing process and the polishing process. The wafer cassette houses a plurality of wafers. Wafers in the same wafer cassette have substantially the same stand-by time. Accordingly, native oxides having substantially the same film thickness are formed on the wafers in the same wafer cassette. From this point of view, time required to polish and remove a native oxide may be set for each wafer cassette. Specifically, an endpoint of a first polishing process may be set for each wafer cassette.

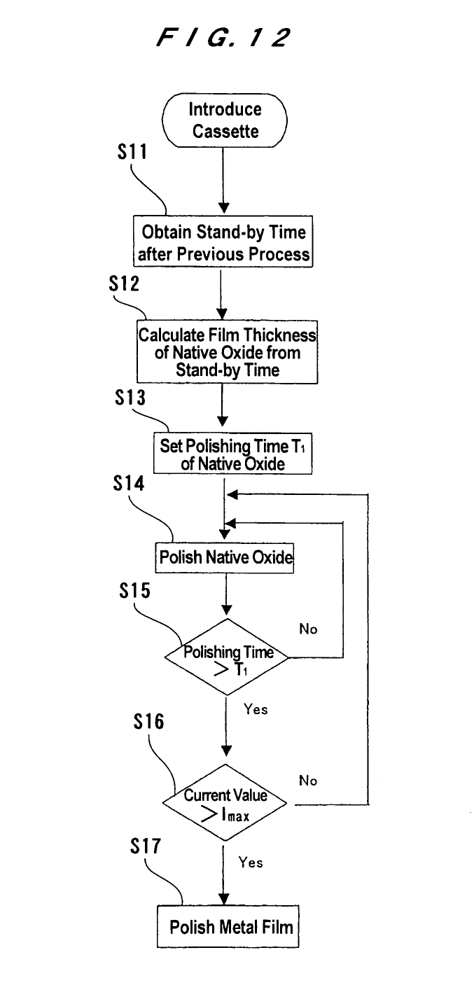

More specifically, as shown in FIG. 12, when a wafer cassette is introduced into the polishing apparatus, a stand-by time of a wafer between the previous process and the polishing process is obtained (step S11). For example, the polishing apparatus and an apparatus used in the previous process are connected via a network so as to transmit data therebetween. When a wafer cassette is placed on a loading/unloading stage of the polishing apparatus, an ID code, which is assigned to the wafer cassette, is read by an identification unit. Then, data of a stand-by time from completion of the previous process until the wafer cassette is placed on the loading/unloading stage is obtained via the network based on the ID code.

The film thickness of a native oxide, which is in proportion to the stand-by time, is calculated from the obtained stand-by time by a controller in the polishing apparatus (step S12). Then, a polishing time T₁ required to polish and remove the native oxide is set from the relationship with a polishing rate based on the film thickness of the native oxide (step S13). Then, a first polishing process is started to polish the native oxide of the wafer (step S14). After the polishing time T₁ has elapsed (step S15), the first polishing process is continued until a current flowing through the motor 302 (see FIG. 6) becomes larger than a predetermined current value (threshold value) Iₘₐₓ (step S16). When the motor current becomes larger than the threshold value Iₘₐₓ after the polishing time T₁ has elapsed, a second polishing process is started to polish a metal film formed on the wafer (step S17).

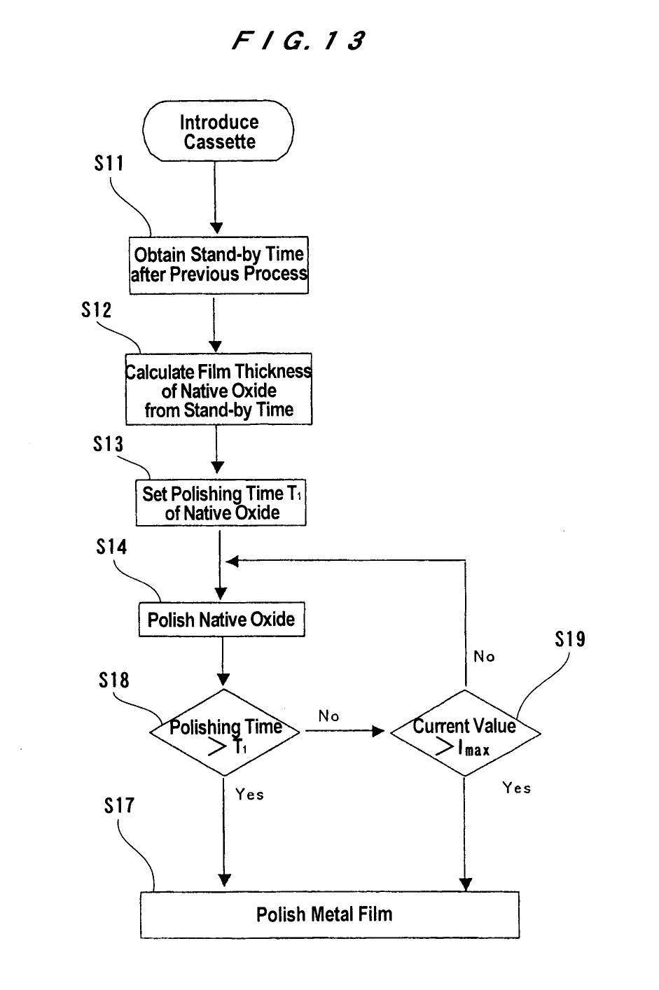

In the example shown in FIG. 12, the first polishing process is continued until the motor current becomes larger than the threshold value Iₘₐₓ after the polishing time T₁ has elapsed. However, processes shown in FIG. 13 may alternatively be performed. Specifically, it is first judged whether or not the polishing time exceeds the polishing time T₁ (step S118). If the polishing time exceeds the polishing time T₁, a second polishing process is started (step S17). If the polishing time does not exceed the polishing time T₁, it is judged whether or not the motor current is larger than the threshold value Iₘₐₓ (step S19). If the motor current is larger than the threshold value Iₘₐₓ, a second polishing process is started (step S17). If the motor current is not larger than the threshold value Iₘₐₓ, the first polishing process is continued. In this case, the judgment on whether the motor current is larger than the threshold value Iₘₐₓ may be performed after the judgment on whether the polishing time exceeds the polishing time T₁.

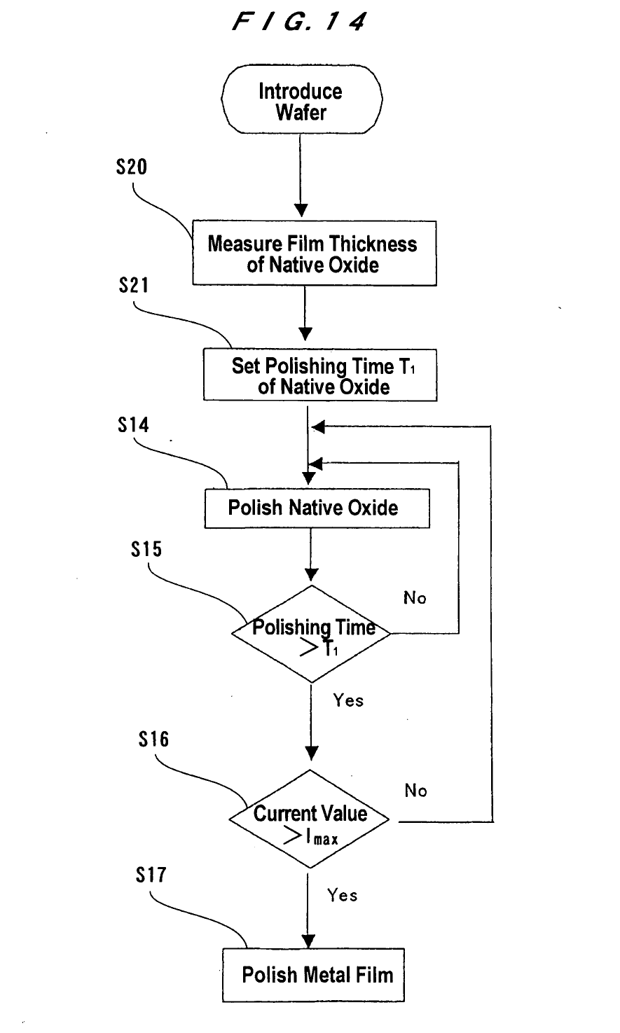

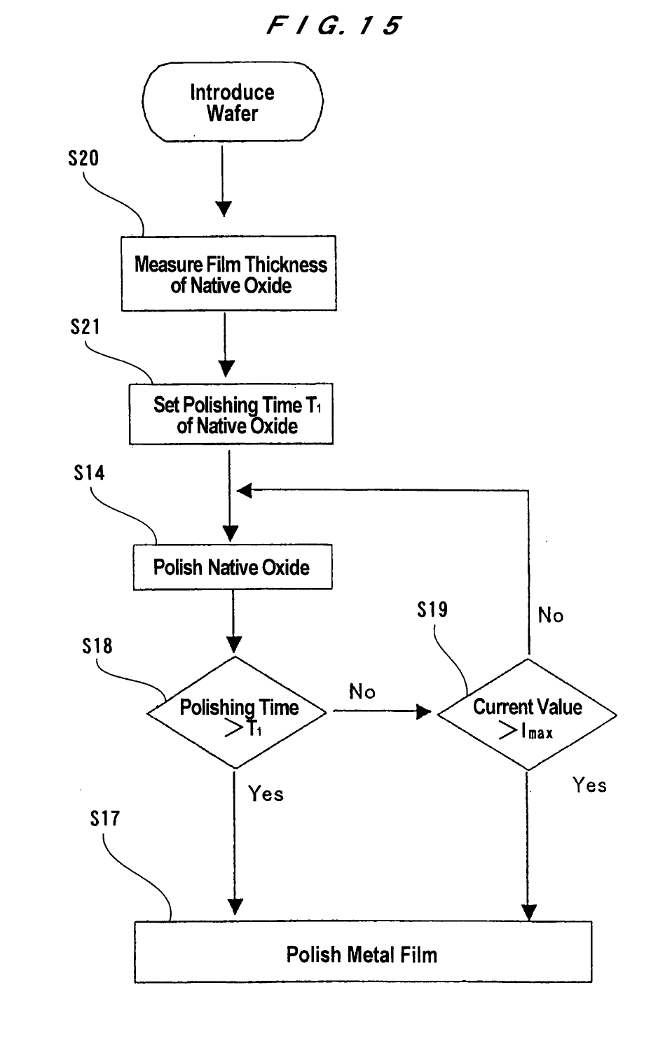

In the examples shown in FIGS. 12 and 13, the film thickness of a native oxide is calculated based on a stand-by time from the previous process. However, as shown in FIGS. 14 and 15, after a wafer is introduced into the polishing apparatus, the film thickness of a native oxide may be measured by a film thickness measurement unit employing, for example, a Fourier transform infrared spectrometer (FT-IR) (step S20). Then, a polishing time T₁ required to polish and remove the native oxide may be set from the relationship with a polishing rate based on the film thickness of the native oxide (step S21). The processes shown in FIGS. 14 and 15 may be performed for each wafer. However, since native oxides having substantially the same film thickness are formed on wafers in the same wafer cassette as described above, the processes shown in FIGS. 14 and 15 may be performed for only the first wafer in the same wafer cassette, for only first several wafers in the same wafer cassette, or for one of each set of a predetermined number of wafers in the same wafer cassette.

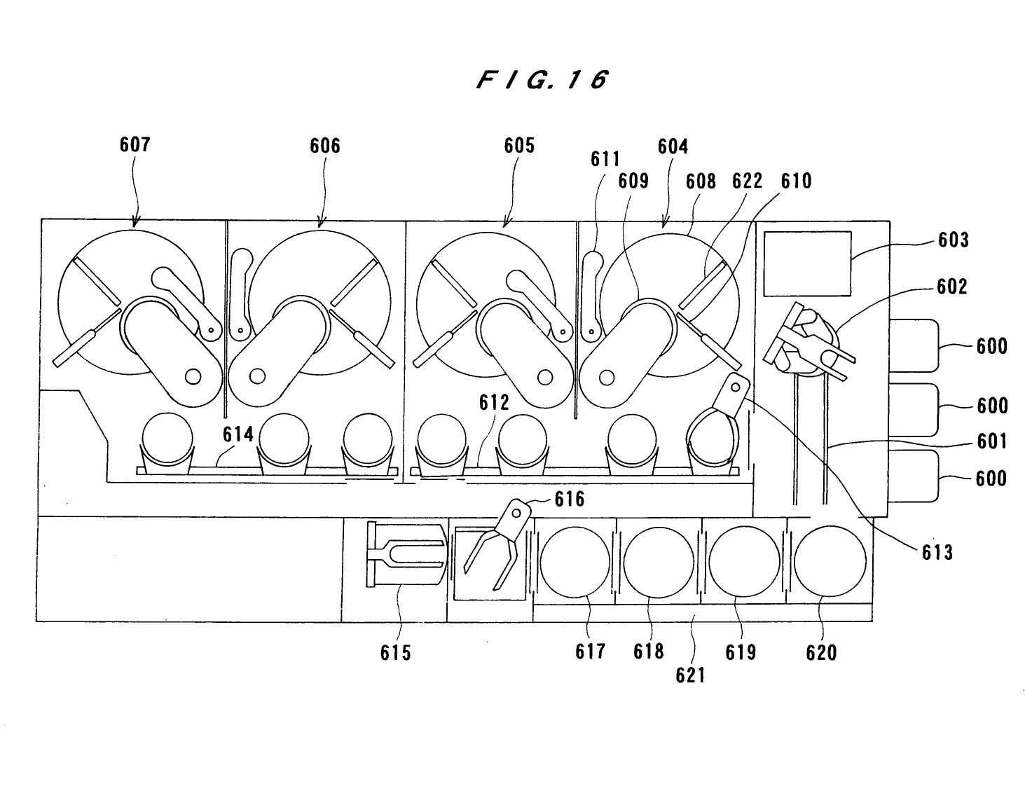

The aforementioned substrate processing method according to the present invention is applicable not only to the polishing apparatuses shown in FIGS. 1 and 4, but also to various substrate processing apparatuses. For example, the substrate processing method according to the present invention is applicable to a substrate processing apparatus shown in FIG. 16. The substrate processing apparatus shown in FIG. 16 has three loading/unloading stages 600 on which wafer cassettes are placed, a moving mechanism 601 arranged along an array of the loading/unloading stages 600, and a film thickness measurement unit 603 disposed adjacent to the moving mechanism 601. The moving mechanism 601 includes a first transfer robot 602 having two hands accessible to the wafer cassettes on the loading/unloading stages 600 and the film thickness measurement unit 603.

As shown in FIG. 16, the substrate processing apparatus includes four polishing units 604 to 607 arranged along a longitudinal direction of the apparatus. Each of the polishing units 604 to 607 has a polishing table 608 having a polishing surface, a top ring 609 for holding a semiconductor wafer and pressing the semiconductor wafer against the polishing table 608, a polishing liquid supply nozzle 610 for supplying a polishing liquid and a dressing liquid (e.g. water) onto the polishing table 608, a dresser 611 for dressing the polishing table 608, and an atomizer 622 for jetting a mixture of liquid (e.g. pure water) and gas (e.g. nitrogen) in an atomized state through one or more nozzles onto the polishing surface.

The substrate processing apparatus also includes a first linear transporter 612 for transferring wafers, a reversing machine 613 for reversing a wafer received from the first transfer robot 602, and a second linear transporter 614 for transferring wafers. The first linear transporter 612 is disposed near the polishing units 604 and 605 along the longitudinal direction of the apparatus. The reversing machine 613 is disposed on the first linear transporter 612 near the loading/unloading stages 600. The second linear transporter 614 is disposed near the polishing units 606 and 607 along the longitudinal direction of the apparatus.

The substrate processing apparatus has a second transfer robot 615, a reversing machine 616 for reversing a wafer received from the second transfer robot 615, four cleaning devices 617 to 620 for cleaning a polished semiconductor wafer, and a transfer unit 621 for transferring a wafer between the reversing machine 616 and the cleaning devices 617 to 620. The second transfer robot 615, the reversing machine 616, and the cleaning devices 617 to 620 are arranged in series along the longitudinal direction of the apparatus.

In the substrate processing apparatus having the above arrangement, a wafer in a wafer cassette is introduced through the reversing machine 613, the first linear transporter 612, and the second linear transporter 614 into the respective polishing units 604 to 607. In each of the polishing units 604 to 607, the aforementioned substrate processing method according to the present invention can be performed. The polished wafer is introduced through the second transfer robot 615 and the reversing machine 616 into the cleaning devices 617 to 620 and cleaned therein. The cleaned wafer is returned to the wafer cassette by the first transfer robot 602.

In the above embodiments, a chemical mechanical polishing unit for performing a chemical mechanical polishing process on a metal film of a substrate is employed as a planarization unit for planarizing a metal film of a substrate. However, a planarization unit is not limited to a chemical mechanical polishing unit. For example, instead of a chemical mechanical polishing unit, a planarization unit may comprise an electrochemical process unit for performing an electrochemical process on a metal film of a substrate with an electrolyte or ultrapure water, or a combined electrochemical process unit for performing a combined electrochemical process, which includes an electrochemical process and a mechanical polishing process, on a metal film of a substrate.

For example, when the aforementioned two-stage polishing method is applied to an electrochemical process, by properly adjusting a current or a voltage during a first polishing process and a current or a voltage during a second polishing process, a metal film of a wafer can be removed in a state such that a native oxide has been removed from the metal film on the wafer. Accordingly, it is possible to achieve uniform planarization.

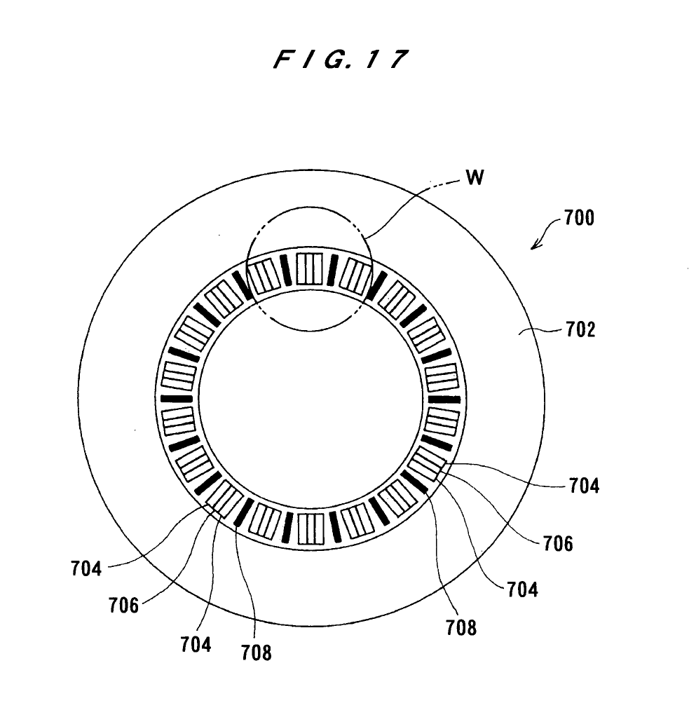

FIG. 17 is a plan view showing an example of an electrochemical process unit 700 which can be employed instead of the aforementioned chemical mechanical polishing units. The electrochemical process unit 700 has a circular electrode table 702. The electrode table 702 is rotatable and has process electrodes 706 and feeding electrodes 708 arranged alternately along a circumferential direction. Each of the process electrodes 706 has water supply nozzles 704 disposed on both sides thereof. The process electrodes 706 and the feeding electrodes 708 are connected to a power supply (not shown).

While the electrode table 702 is rotated, pure water or ultrapure water is supplied from the water supply nozzles 704. The wafer W, which is rotated as needed, is processed by the process electrodes 706 and the feeding electrodes 708 that are moved to a location facing the wafer W according to rotation of the electrode table 702.

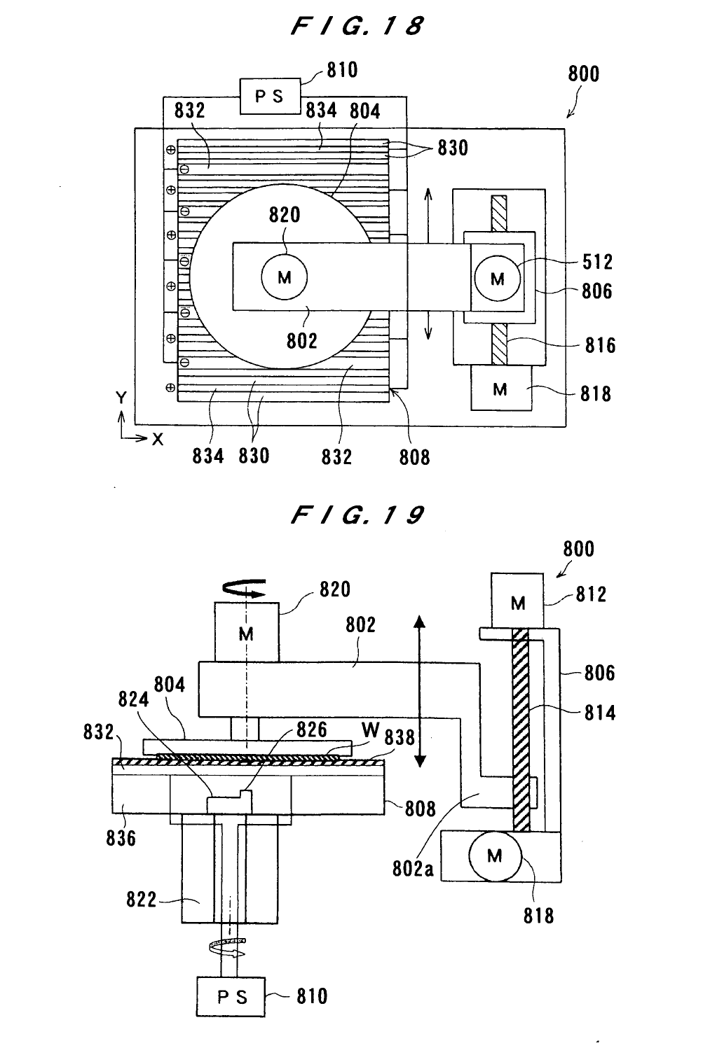

FIG. 18 is a plan view showing an example of a combined electrochemical process unit 800 which can be employed instead of the aforementioned chemical mechanical polishing units. FIG. 19 is a vertical cross-sectional view of FIG. 18. As shown in FIGS. 18 and 19, the combined electrochemical process unit 800 has an arm 802, a wafer holder 804 extending from a free end of the arm 802, a movable frame 806 to which the arm 802 is attached, a rectangular process table 808, and a power supply 810 provided in the process table 808. The arm 802 can be vertically moved and reciprocated on the horizontal plane. The wafer holder 804 attracts and holds the wafer W in a state such that a surface (to be processed) of the wafer W faces downward. In the example shown in FIG. 18, the process table 808 has a size larger than the outside diameter of the wafer W held by the wafer holder 804.

The movable frame 806 has a motor 812 disposed at an upper portion thereof for vertically moving the arm 802. A vertically extending ball screw 814 is coupled to the motor 812. The arm 802 includes a base portion 802a attached to the ball screw 814. Accordingly, when the motor 812 is driven, the arm 802 is moved vertically via the ball screw 814. The movable frame 806 is attached to a horizontally extending ball screw 816. When a motor 818 is driven, the movable frame 806 and the arm 802 are reciprocated on the horizontal place.

The wafer holder 804 is coupled to a motor 820 provided on a free end of the arm 802. When the motor 820 is driven, the wafer holder 804 is rotated about its axis. As described above, the arm 802 can be vertically moved and reciprocated on the horizontal plane. Thus, the wafer holder 804 can be vertically moved and reciprocated on the horizontal plane together with the arm 802.

Further, a hollow motor 822 is disposed below the process table 808. The hollow motor 822 includes a main shaft 824 having a driving end 826 located eccentrically from the center of the main shaft 824. The process table 808 is rotatably coupled to the driving end 826 at the center of the process table 808 via bearings (not shown). Three or more rotation prevention mechanisms (not shown) are provided along a circumferential direction between the process table 808 and the hollow motor 822. The rotation prevention mechanisms allow the process table 808 to make a scroll movement (orbital movement or translational rotation) when the hollow motor 822 is driven.

As shown in FIG. 18, the process table 808 includes a plurality of mechanical process sections 830 and a plurality of process electrodes 832 and feeding electrodes 834. For example, the mechanical process sections 830 are formed by fixed abrasive particles. The process electrodes 832 and the feeding electrodes 834 form electrochemical process sections. As shown in FIG. 19, the process table 808 has a flat base plate 836 below the process electrodes 832 and the feeding electrodes 834. The process electrodes 832 and feeding electrodes 834, which extend along X direction (see FIG. 18), are arranged alternately on an upper surface of the base plate 836 and spaced from each other by predetermined distances. The process electrodes 832 and the feeding electrodes 834 are connected to the power supply 810. The mechanical process sections 830, which extend along X direction (see FIG. 18), are disposed on both sides of each feeding electrode 834. Each of upper surfaces of the process electrodes 832 is covered with an ion exchanger 838 having a semicircular cross-section.

The power supply 810 applies a predetermined voltage between the process electrodes 832 and the feeding electrodes 834. On the process electrodes (cathodes) 832, a conductive film on a surface of the wafer W is subjected to an electrochemical process due to hydrogen ions or hydroxide ions generated by the ion exchangers 838. At that time, the wafer is processed at portions facing the process electrodes 832. By moving the wafer W and the process electrodes 832 relative to each other, the entire surface of the wafer W can be processed. Simultaneously, by pressing the mechanical process sections 830 against the surface of the wafer W, the conductive film on the surface of the wafer W is subjected to a mechanical process in the presence of pure water or ultrapure water.

Although certain preferred embodiments of the present invention have been shown and described in detail, it should be understood that various changes and modifications may be made therein without departing from the scope of the appended claims.

1. A substrate processing method comprising:
removing a native oxide of a metal film formed on a substrate; and
planarizing the metal film formed on the substrate after said removing process.

2. The substrate processing method as recited in claim 1, wherein said removing process comprises a wet process using a chemical liquid capable of dissolving the native oxide of the metal film on the substrate.

3. The substrate processing method as recited in claim 2, wherein the chemical liquid comprises an acidic chemical liquid or a chelating agent solution for forming a soluble complex.

4. The substrate processing method as recited in claim 1, wherein said removing process comprises a dry process using a gas capable of reducing or etching the native oxide of the metal film on the substrate.

5. The substrate processing method as recited in claim 4, wherein the gas comprises a mixed gas of hydrogen and argon.

6. The substrate processing method as recited in claim 1, wherein said planarizing process comprises a chemical mechanical polishing process, an electrochemical process, or a combined electrochemical process of an electrochemical process and a mechanical polishing process.

7. A method of polishing a substrate having a metal film formed thereon by pressing the substrate against a polishing surface, said method comprising:
initially polishing the substrate to remove a native oxide of the metal film; and
subsequently polishing the substrate to remove the metal film of the substrate.

8. The method as recited in claim 7, wherein said initial polishing process comprises pressing the substrate against the polishing surface under a first pressure,
wherein said subsequent polishing process comprises pressing the substrate against the polishing surface under a second pressure different than the first pressure.

9. The method as recited in claim 8, wherein the first pressure is larger than the second pressure.

10. The method as recited in claim 7, wherein said initial polishing process comprises supplying a first polishing liquid to the polishing surface,
wherein said subsequent polishing process comprises supplying a second polishing liquid, different than the first polishing liquid, to the polishing surface.

11. The method as recited in claim 7, further comprising supplying water to the polishing surface between said initial polishing process and said subsequent polishing process while pressing the substrate against the polishing surface.

12. The polishing method as recited in claim 7, further comprising detecting an endpoint of said initial polishing process based on a frictional force produced between the substrate and the polishing surface.

13. A method of polishing a substrate having a metal film formed thereon by pressing the substrate against a polishing surface, said method comprising:
initially polishing the substrate by pressing the substrate against the polishing surface under a first pressure;
supplying water to the polishing surface after said initial polishing process while pressing the substrate against the polishing surface; and
subsequently polishing the substrate by pressing the substrate against the polishing surface under a second pressure different than the first pressure after said supplying process.

14. A substrate processing apparatus comprising:
a process unit configured to remove a native oxide of a metal film formed on a surface of a substrate; and
a planarization unit configured to planarize the metal film of the substrate.

15. The substrate processing apparatus as recited in claim 14, wherein said process unit comprises a wet process unit configured to dissolve the native oxide of the metal film in a chemical liquid.

16. The substrate processing apparatus as recited in claim 15, wherein the chemical liquid comprises an acidic chemical liquid or a chelating agent solution for forming a soluble complex.

17. The substrate processing apparatus as recited in claim 14, wherein said process unit comprises a dry process unit configured to reduce or etch the native oxide of the metal film with a gas.

18. The substrate processing apparatus as recited in claim 17, wherein the gas comprises a mixed gas of hydrogen and argon.

19. The substrate processing apparatus as recited in claim 14, wherein said planarization unit comprises a chemical mechanical polishing unit configured to polish the metal film of the substrate by chemical mechanical polishing, an electrochemical process unit configured to perform an electrochemical process on the metal film of the substrate, or a combined electrochemical process unit configured to perform a combined electrochemical process, which includes an electrochemical process and a mechanical polishing process, on the metal film of the substrate.
